(19) United States
(12) Patent Application Publication
(10) Pub. No.: US 2006/0109638 A1
(43) Pub. Date: May 25, 2006

(54) Fastening mechanism for interface card

(75) Inventor: Chun-Hung Lee, Taipei County (TW)

Correspondence Address: BIRCH STEWART KOLASCH & BIRCH, PO BOX 747, FALLS CHURCH, VA, 22040-0747, US

(73) Assignee: TYAN COMPUTER CORP

(21) Appl. No.: 11/271,830

(22) Filed: Nov. 14, 2005

(30) Foreign Application Priority Data
Nov. 19, 2004 (TW) 93135740

(51) Int. Cl. H05K 7/14; H05K 7/18

(52) U.S. Cl. 361/801

(57) ABSTRACT

A fastening mechanism for an interface card is provided. After a tail of a connection plate of the interface card is aligned with a positioning member of the chassis, a latch member pivoted directly/indirectly on the chassis may be swiveled to press the tail of the connection plate toward the positioning member. When a chassis panel of the chassis is installed, the chassis panel can press and secure the latch member. Hence the connection plate can be fastened securely on the chassis without using screws.

### CROSS-REFERENCE TO RELATED APPLICATIONS

This non-provisional application claims priority under 35 U.S.C. § 119(a) on Patent Application No(s). 093135740 filed in Taiwan, R.O.C. on Nov. 19, 2004, the entire contents of which are hereby incorporated by reference.

### BACKGROUND OF THE INVENTION

1. Field of Invention

The present invention relates to fastening configuration of interface card, in particular, to a fastening mechanism for fastening interface card without using screws.

2. Related Art

Computer applications have become a portion of people's lives now. With advance of technologies, assembly of computer hardware has become not as complicated as in the past. These days much hardware is designed with plug-and-play concept. Hence the task of assembling a computer and adding or upgrading hardware can be done by general users.

Computer hardware is upgraded very fast. Therefore, the life cycle of computer hardware is shortened. Replacement of the hardware often has to be done even before its capacity is fully exhausted. Nowadays computer users often have to install, replace or upgrade new hardware on the computer. This is especially true for installation of interface cards, such as sound cards, video cards, network cards, and the like.

In general, the interface card is a bridge to connect the host with peripheral devices. During installation, the case of the computer host has to be removed. Then the interface card is inserted into a desired slot on the motherboard. The interface card has a connection port end on another end to be coupled with an anchor slot on the rear side of the host. Then the connection port end is fastened to an anchor hole on one side through screws, to fasten the interface card securely.

Refer to FIGS. 1 and 2 for installing a conventional interface card. To install an interface card 80 on a computer motherboard, the interface card 80 has coupling pins 82 on one end and an insertion pin 832 on the bottom of a connection plate 83, to be inserted respectively into an interface card adapter slot 91 and a pin hole 93 on the motherboard. Then the connection plate 83 on one end of the interface card 80 is aligned with a connection port anchor slot 92, with an anchor hole 831 aligned with a screw hole 924 on one side of the connection port anchor slot 92. Then a screw 70 is inserted through the anchor hole 831 to the screw hole 924 for fastening the interface card with the computer motherboard.

In the process of installing or removing the interface card, fastening and unfastening screws are most time-consuming and tedious. As the screws usually are small, fastening is troublesome. Also, it frequently happens that the screws drop onto the motherboard and scrap the surface of the motherboard.

Taiwan patent publication No. 588819 discloses another fastening method about an interface card positioning device. A positioning plate mounted with the interface card is coupled to an insert slot on the chassis. A fastening plate configured pivotally on the chassis is rotatable to cover and press on an end of the positioning plate. The other end of the positioning plate is fastened to the chassis through screws or other means. Such a design also involves screws. Hence the problem of dropping the screws still easily happens.

To remedy the aforesaid problem, interface card fastening structures without using screws have been developed. Reference can be found in Taiwan patent publication numbers 530963, 584224 and 584254.

Taiwan patent publication No. 530963 discloses an interface card fastening mechanism capable of fast installation and removal. By a lid pivoted to the chassis, when a U-shaped slot of an interface card aligned with a corresponding hole of the chassis, an insert piece of the lid is inserted into the hole to confine the interface card. And the lid is swiveled to be anchored by a latch unit. By moving the lid, a front blocking piece and a side blocking piece to confine the interface card from moving in various dimensions (up and down, front and rear sides, left and right sides), the interface card can be fastened.

Taiwan patent publication No. 584224 discloses an improved latch and anchor mechanism for an interface card. A thin board pivoted to the chassis is capable of swiveling to a position for engaging with a connection unit by a latch to press plural lid plates (anchor plates of a number of interface cards). A flange of the connection unit is for engaging with a cavity of the latch. And a second press member of the connection unit is configured for releasing the cavity of the latch from the flange. However, the board is lengthy and anchored on the chassis with one end. It is hard to keep the same anchoring force along every point on the board. Fastened interface card is easily loosening off.

Taiwan patent publication No. 584254 discloses a latch type locking device for fastening a computer interface card into a predetermined card slot. The locking device is a separated apparatus, capable of inserting into a locking slot on a computer chassis and engaging with a positioning plate of the interface card. This case needs a hook extended from the positioning plate of the computer interface card to anchor on a space plate of the computer chassis in advance. Otherwise the positioning plate would possibly loose off horizontally. However, said hook is not a standard design for every interface card in the industry. The locking device actually does not provide limitation for horizontal movement of the interface card.

Refer to FIGS. 3A and 3B for another conventional installation structure of an interface card. The interface card has a connection plate 61 corresponding to a connection port anchor slot 42 of the chassis 40. After the connection plate 61 has been leaned against an alignment latch member 20 of the chassis 40, a latch member 10 pivoted to the chassis 40 may be swiveled. The latch member 10 has a trough 12 to be anchored by a flange 31 of a latch member 30 of the chassis 40.

### SUMMARY OF THE INVENTION

In view of the aforesaid problems, the primary object of the present invention is to provide a fastening mechanism for an interface card to securely fasten a connection plate of an interface card to an anchor slot of a chassis, without using screws. Installation and removing can be done quickly to reduce the assembly process and save labor costs.

To achieve the foregoing object, the interface card fastening structure according to the present invention aims to securely fasten a connection plate on an interface card in an anchor slot of a chassis. The chassis has a chassis panel.

The fastening mechanism according to the present invention comprises a latch member, a positioning member and a holding member. The latch member abutting the anchor slot is pivoted to the chassis. The positioning member is located on the chassis in a protrusive manner, adjacent to the anchor slot and opposing the latch member. The hold member is located on one side of the chassis panel.

By means of the structure set forth above, the connection plate may be aligned with the anchor slot and leans against the positioning member. The latch member may be swiveled and lean against the positioning member. After the chassis panel is installed, the holding member can anchor the latch member so that the connection plate can be securely fastened in the anchor slot on the chassis, without using screws. Installation and removing can be done quickly. The assembly process is reduced, and labor costs are lower.

Further scope of applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given in the illustration below only, and thus is not limitative of the present invention, wherein:

FIG. 1 is an exploded view of an installation structure of a conventional interface card;

FIG. 2 is a schematic view of an installation structure of a conventional interface card;

FIGS. 3A and 3B are schematic views of another installation structure of a conventional interface card;

FIG. 4 is an exploded view of an embodiment in accordance with the present invention;

FIG. 5 is a schematic view of the embodiment in accordance with the present invention;

FIGS. 6A through 6E are schematic views of the interface card in fastening operations, in accordance with the embodiment of the present invention; and

FIG. 7 is a schematic view of the interface card of on an inner side of the chassis in accordance with the embodiment of the present invention.

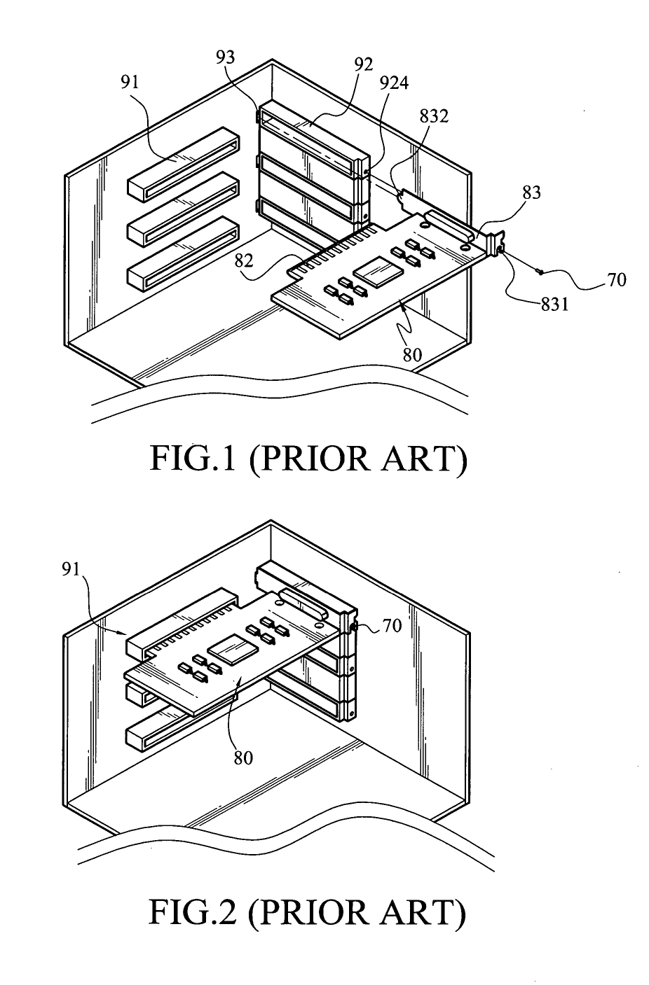

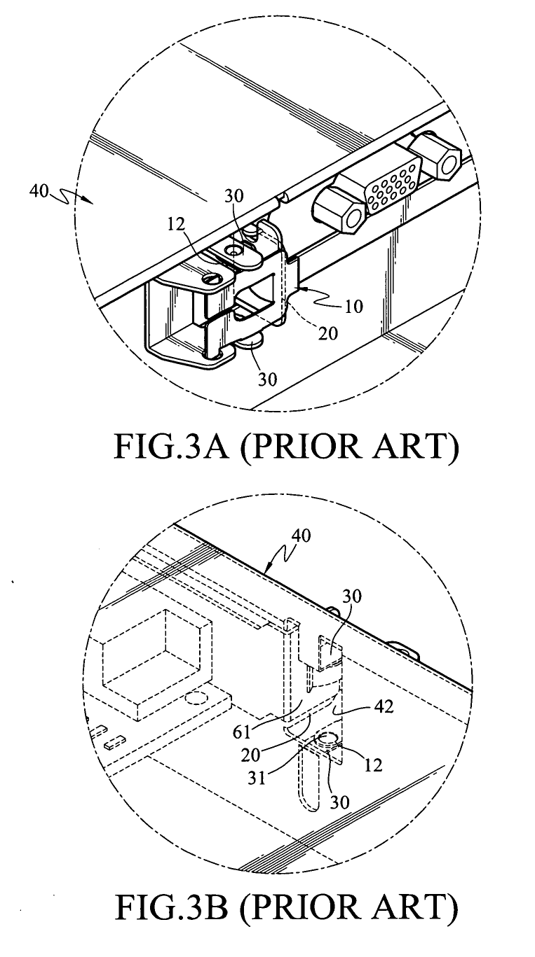

### DETAILED DESCRIPTION OF THE INVENTION

A fastening mechanism according to an embodiment of the present invention aims to securely fasten a tail of a connection plate of an interface card to a chassis that covers a computer system.

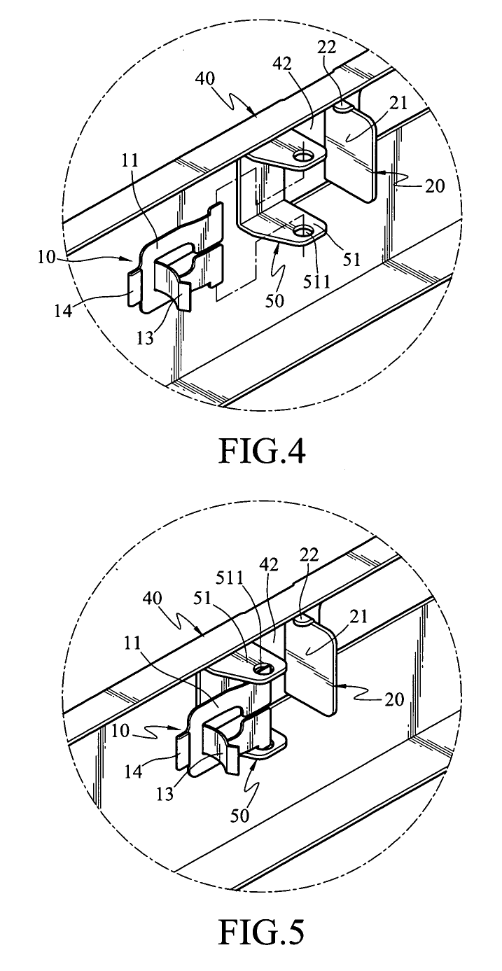

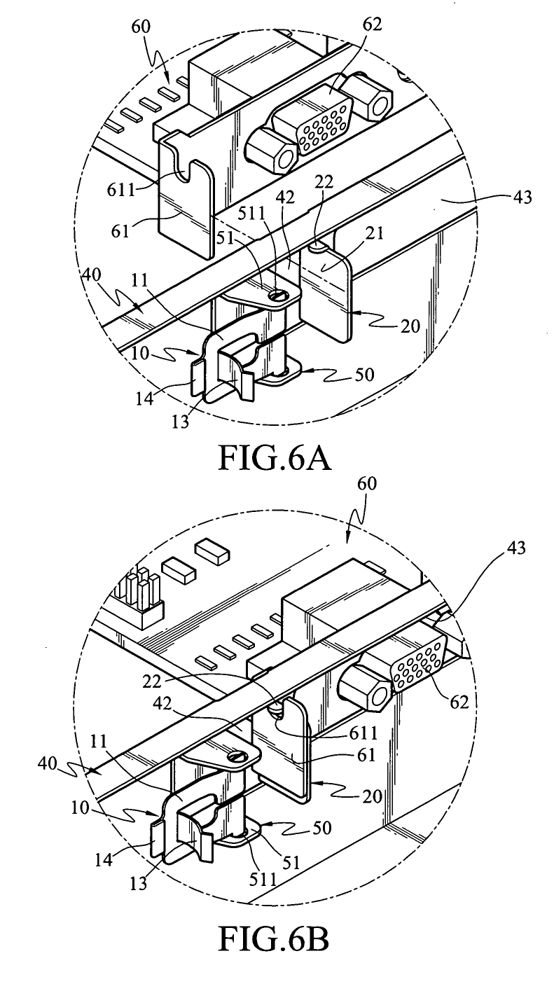

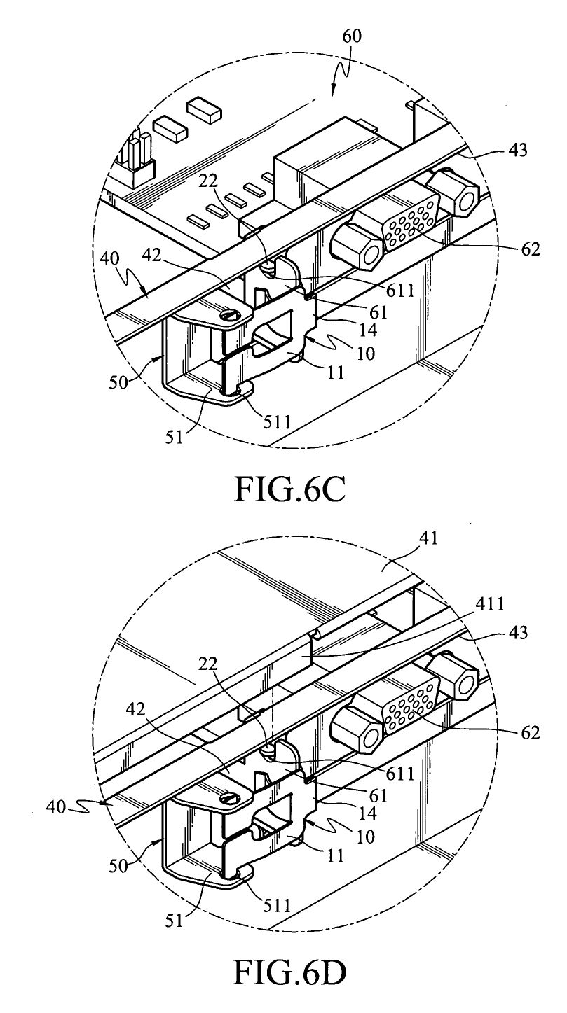

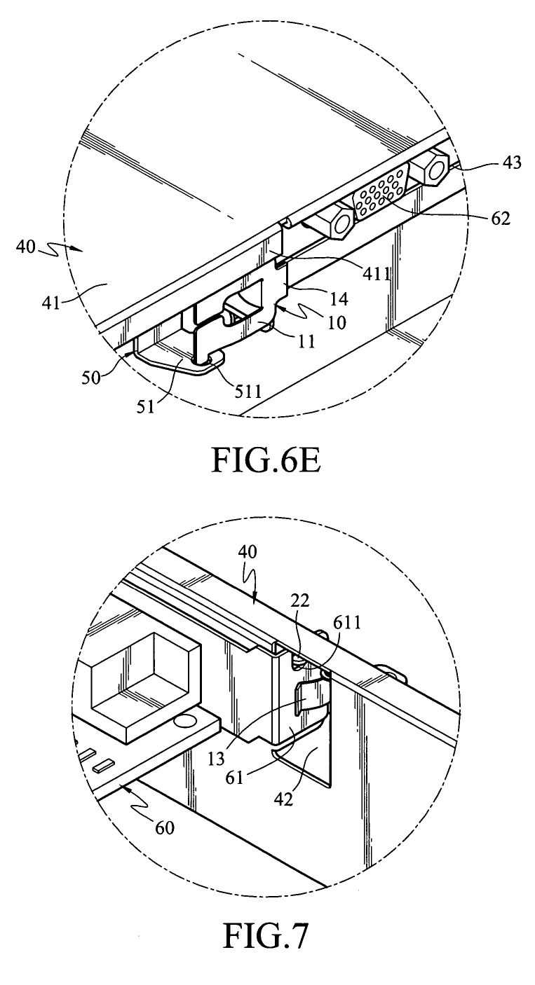

The fastening mechanism disclosed in the following embodiment comprises a latch member 10 (FIGS. 4 to 6E), a positioning member 20 (FIGS. 4 to 6B), a holding member 411 (FIGS. 6D and 6E) and a pivot bracket 50 (FIGS. 4 to 6E).

Referring to FIGS. 4 and 5, the chassis 40 has an anchor slot 42 adjacent to the flat positioning member 20. A positioning piece 22 is formed on an edge of the positioning member 20. The U-shaped pivot bracket 50 outside the chassis 40 is configured near the anchor slot 42 and opposite to the positioning member 20.

The latch member 10 includes a plate type latch body 11, an elastic blade 13, a draw portion 14 and the stub shafts 16. When the latch member 10 is fastened, the latch body 11 will press on an external edge of the tail of the connection plate 61. The latch member 10 has protrusive stub shafts 16 on two ends to rotatablly engage with two lugs 51 of the pivot bracket 50. Each lug 51 has an aperture 511 corresponding to the stub shafts 16 of the latch member 10. Also the latch body 11 is hollowed out, contributing to the flexibility of the stub shafts 16 for easy installation. Hence the latch member 10 abutting the anchor slot 42 can be pivoted to the pivot bracket 50 operatively.

The lengthily V-shaped elastic blade 13 is extended from the plate type latch body 11. It is to provide a press force toward the positioning member 20 when the latch member 10 is rotated to couple with the positioning member 20.

The draw portion 14 is for users to easily operate the latch member 10 pivotally. It may be a bend-back end of the latch member 10 to form a protrusive edge for hooking on the external edge of the positioning member 20, or on the external edge of the tail of the connection plate 61.

In practice, the latch member may be directly pivoted on the chassis without the pivot bracket. Only need to modify the shape of the latch member to maintain the same functions as mentioned above, and tiny structure modification of the chassis for the latch member to operatively rotate.

The positioning member 20 is standing adjacent to the anchor slot 42 and located on the outside of the chassis 40 in a protrusive manner, opposing the latch member 10. The positioning member 20 includes a flat body 21 and a positioning piece 22.

The flat body 21 and the elastic blade 13 can jointly clamp the tail of the connection plate 61 while the latch member 10 is being anchored.

The positioning piece 22 is extended sideward from the flat body 21 corresponding to a notch 611 of the tail of the connection plate 61 (FIG. 6A-6D). Generally, the notch is very common in the industry for operation of a screw.

The holding member 411 (FIG. 6D-6E) is a bended part of the removable chassis panel 41, located on the lateral side of the chassis panel 41. The chassis panel 41 is also an assembly of the chassis 40 to cover one or more sides of the computer system.

Refer to FIGS. 6A through 6E, and 7 for the embodiment in used condition. First, from the inside of the chassis 40, move the interface card 60 and reach outward the bended tail of the connection plate 61 into the anchor slot 42, with the positioning piece 22 wedging in the notch 611 of the tail of the connection plate 61. Meanwhile, make the tail of the connection plate 61 leaning against the flat body 21 of the positioning member 20. Then the main body of the connection plate 61 should lean on a connection slot 43 of the chassis 40. And one or more connection port 62 should pass through the connection slot 43 and reveal outside the chassis 40. Next, by the stub shafts 16 as an axle center, one can pull the draw portion 14 to swivel the latch member 10 relative to the pivot bracket 50 and make the elastic blade 13 press the connection plate 61 toward the flat body 21 of the positioning member 20. The elastic blade 13 and the flat body 21 can jointly clamp the tail of the connection plate 61, with the plate type latch body 11 in contact with (or close to) the edge of the tail of the connection plate 61. The protrusive edge of the draw portion 14 may anchor the external edge of the positioning member 20, or the external edge of the tail of the connection plate 61. The chassis panel 41 will strengthen the latch member 10 to remain anchored. After the chassis panel 41 is installed inwards (opposite to the main installation direction of the interface card 60), the holding member 411 anchors the latch member 10 so that the tail of the connection plate 61 can be fastened firmly in the anchor slot 42. Namely, the main body of the connection plate 61 is also fastened to the connection slot 43 of the chassis 40.

Thus, the interface card fastening mechanism according to the embodiment of the present invention can be installed and removed quickly without using screws and tools. The installation or removing process is simpler, so labor costs may be reduced.

Conclusively, the present invention mainly employs a positioning member of the chassis and an elastic blade of a latch member to clamp a tail of the connection plate of an interface card. To prevent the tail of the connection plate from loosing off, the positioning member has a positioning piece for engaging a notch on the tail of the connection plate. Furthermore, a holding member of a chassis panel secures the latch member and keeps the elastic blade pressing on the tail of the connection plate.

In practice of the present invention, the structure of the latch member is not limited to above-mentioned embodiment. Any change of the latch member that provides an elastic element to give force towards the positioning member, combined with the operation of the chassis panel, should be included in the present invention. In some solutions, a flat latch member may be bended into lengthy N-shape to give operative flexibility as an elastic element.

The present invention can hold more than one interface cards by firmly fastening the connection plate in practice. Additionally, all the features of the present invention can all be configured inside the chassis, opposite to the solutions shown in the drawings. Then the anchor slot will be no longer necessary. The installation direction of the chassis panel will not affect its function. The requirement of the chassis panel is only to give a holding force to the latch member when it is installed correctly.

Knowing the present invention being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A fastening mechanism for fastening a connection plate of an interface card onto a chassis, comprising:
a positioning member standing on the chassis for an tail of the connection plate to lean thereon;
a latch member configured pivotally on the chassis, rotatable to lean on the positioning member and press the tail of the connection plate toward the positioning member; and
a holding member located on a removable chassis panel of the chassis to operatively keep the latch member in contact with the tail of the connection plate.

2. The fastening mechanism of claim 1, wherein the latch member comprises a plate type latch body and an elastic blade, when the latch body being rotated to lean on an edge of the positioning member or of the tail of the connection plate, the elastic blade extending from the plate type latch body giving a force to press the tail of the connection plate toward the positioning member.

3. The fastening mechanism of claim 2, wherein the positioning member includes a flat body and an positioning piece, the flat body of the positioning member and the elastic blade of the latch member jointly clamping the tail of the connection plate while the latch member is being secured by the holding member, the positioning piece being extending from the flat body for wedging a notch formed on the tail of the connection plate.

4. The fastening mechanism of claim 2, wherein the elastic blade is lengthy V-shape.

5. The fastening mechanism of claim 1, wherein the chassis further comprising a pivot bracket, the pivot bracket having two lugs each having an aperture for pivoting the latch member.

6. The fastening mechanism of claim 1, wherein the latch member has two protrusive stub shafts for pivoting on the chassis.

7. The fastening mechanism of claim 6, wherein the latch member is hollowed out to provide flexibility for the two stub shafts.

8. The fastening mechanism of claim 1, wherein the latch member further comprises a draw portion for receiving forces thereon.

9. The fastening mechanism of claim 1, wherein the draw portion is a bend-back end of the latch member to form a protrusive edge for hooking on an edge of the positioning member or of the tail of the connection plate.

10. The fastening mechanism of claim 1, wherein an anchor slot of the chassis is located between the positioning member and a position for pivoting the latch member.

11. A fastening mechanism for fastening a connection plate of an interface card onto a chassis, comprising:
a positioning member standing on the chassis for an tail of the connection plate to lean thereon;
a latch member configured pivotally on the chassis, rotatable to lean on the positioning member and press the tail of the connection plate toward the positioning member; and
a removable chassis panel of the chassis to operatively keep the latch member in contact with the tail of the connection plate.

12. The fastening mechanism of claim 11, wherein the latch member comprises a plate type latch body and an elastic blade, when the latch body being rotated to lean on an edge of the positioning member or of the tail of the connection plate, the elastic blade extending from the plate type latch body giving a force to press the tail of the connection plate toward the positioning member.

13. The fastening mechanism of claim 12, wherein the positioning member includes a flat body and an positioning piece, the flat body of the positioning member and the elastic blade of the latch member jointly clamping the tail of the connection plate while the latch member is being secured by the chassis panel, the positioning piece being extending from the flat body for wedging a notch formed on the tail of the connection plate.

14. The fastening mechanism of claim 11, wherein the chassis further comprising a pivot bracket, the pivot bracket having two lugs each having an aperture for pivoting the latch member.

15. The fastening mechanism of claim 11, wherein the latch member has two protrusive stub shafts for pivoting on the chassis.

16. The fastening mechanism of claim 16, wherein the latch member is hollowed out to provide flexibility for the two stub shafts.

17. The fastening mechanism of claim 11, wherein the latch member further comprises a draw portion for receiving forces thereon.

18. The fastening mechanism of claim 11, wherein the draw portion is a bend-back end of the latch member to form a protrusive edge for hooking on an edge of the positioning member or of the tail of the connection plate.

19. The fastening mechanism of claim 11, wherein an anchor slot of the chassis is located between the positioning member and a position for pivoting the latch member, the tail of the connection plate passing through the anchor slot to reach the positioning member.

20. The fastening mechanism of claim 11, wherein the chassis panel further comprises a holding member located on a lateral side of the chassis panel to secure the latch member.
